(19) United States
(12) Patent Application Publication
(10) Pub. No.: US 2002/0025681 A1
(43) Pub. Date: Feb. 28, 2002

(54) Semiconductor etching apparatus and method of etching semiconductor devices using same

(76) Inventors: Kyeong-Koo Chi, Seoul (KR); Seung-Pil Chung, Seoul (KR)

Correspondence Address: JONES VOLENTINE, L.L.C., Suite 150, 12200 Sunrise Valley Drive, Reston, VA, 20191, US

(21) Appl. No.: 09/793,143

(22) Filed: Feb. 27, 2001

(30) Foreign Application Priority Data
Aug. 30, 2000 (KR) 2000-50786

(51) Int. Cl. H01L 21/302; C23F 1/02

(52) U.S. Cl. 438/710; 156/345

(57) ABSTRACT

A semiconductor etching apparatus and a method for etching semiconductor devices using the apparatus. The semiconductor etching apparatus includes a chamber for accommodating a wafer, a radical source for supplying a radical into the chamber, a beam source for supplying ion beams or plasma into the chamber, a wafer stage for supporting and holding the wafer accommodated by the chamber, and a neutralizer for neutralizing charge within the chamber ionized by the ion beams, plasma or the radical. The method of etching semiconductor devices includes the steps of forming a reaction layer on the surface of a semiconductor wafer through radical absorption, and etching the surface of the semiconductor wafer by desorbing the reaction layer formed on the surface of the semiconductor wafer.

### BACKGROUND OF THE INVENTION

1. Field of the Invention

The present invention relates to a semiconductor manufacturing apparatus and method, and more particularly, to a semiconductor etching apparatus and a method for etching semiconductor devices using the same.

2. Description of the Related Art

As semiconductor devices become smaller and more densely integrated, the difficulty in manufacturing semiconductor devices increases. In particular, as a photolithography margin in a minute pattern gets narrower, it becomes more difficult to perform a small contact process. To overcome this problem, a self-aligned contact (SAC) process has been developed and used.

The SAC process relies on exploiting the etching selectivity between two different insulation layers during the formation of a contact. For the SAC process, Si₃N₄ layers are widely used as spacers and etching stoppers when etching SiO₂ layers. In recent efforts to improve the etching selectivity of a SiO₂ layer to a Si₃N₄ layer, an approach of increasing a CFₓ radical concentration within plasma by heating the chamber of an etching apparatus is being studied. In addition, an etching process using C₄F₈, C₅F₈ and C₃F₆ as a gas having a high C/F ratio and a plasma source having a low electron temperature have been developed, and based on these developments, an approach of decreasing excessive F radical caused by excessive dissociation within plasma is being studied.

However, the etching selectivity of a SiO₂ layer to a Si₃N₄ layer which has been improved as the result of the above processes does not exceed 20:1. In addition, although an etching selectivity is adjusted by using a C—F base polymer formed on the surface of a layer during a SAC process employing a plasma etching, since a contact window is narrower in a small pitch device, the C—F polymer frequently causes an etch stop phenomenon during a high selectivity process.

### SUMMARY OF THE INVENTION

To solve the above problems, it is an object of the present invention to provide a semiconductor etching apparatus for etching the surface of a wafer by forming a reaction layer through radical absorption and desorbing the reaction layer using an ion beam or plasma.

It is another object of the present invention to provide a method of etching a wafer surface, that is, the object layer of etching by forming and desorbing a reaction layer.

Accordingly, to achieve one object of the invention, there is provided a semiconductor etching apparatus including a chamber for accommodating a wafer, a radical source for supplying a radical into the chamber, a beam source for supplying ion beams or plasma into the chamber, a wafer stage for supporting and holding the wafer accommodated by the chamber, and a neutralizer for neutralizing charge within the chamber ionized by the ion beams, plasma or the radical.

More preferably, the beam source is an inductive coupled plasma apparatus and can adjust beam energy to be proper to an etching object or etching conditions. The radical source forms the plasma and ejects the radical into the chamber. The neutralizer supplies electrons into the chamber cationized by the ion beams, plasma, or the radical, thereby neutralizing the atmosphere of the chamber. Finally, the wafer stage is provided with a cooling apparatus for cooling the accommodated wafer.

To achieve the other object of the invention, there is provided a method of etching semiconductor devices, including the steps of forming a reaction layer on the surface of a semiconductor wafer through radical absorption, and etching the surface of the semiconductor wafer by desorbing the reaction layer formed on the surface of the semiconductor wafer.

It is preferable that the surface of the semiconductor wafer is composed of two different layers, an etching object layer and the other layer, the reaction layer is formed on the etching object layer and the other layer, and the surface of the semiconductor wafer is etched by desorbing the reaction layer formed thereon such that the etching selectivity of the etching object layer to the other layer is high.

The etching object layer on the surface of the semiconductor wafer can be etched by repeatedly performing the step of forming the reaction layer through radical absorption and the etching step through radical desorption two (2) or more times.

It is preferable that the beam energy of ion beams or plasma is set such that the other layer, except the etching object layer, is rarely etched to increase the etching selectivity when the etching object layer on the surface of the semiconductor wafer is etched, by repeatedly performing the reaction layer forming step through radical absorption and the etching step through radical desorption. The etching object layer may be a SiO₂ layer, and the other layer may be a Si₃N₄ layer. It is preferable that the beam energy of the ion beams or plasma necessary for increasing the etching selectivity of the SiO₂ layer to the Si₃N₄ layer is 90-110 eV.

The radical absorption is accomplished using a radical source for supplying a radical into a chamber accommodating a wafer. It is preferable that a mixed gas of a gas containing H and N and a gas containing F is used as the radical source gas. The mixed gas of a gas containing H and N and a gas containing F preferably has a H/F ratio of 1.0 or higher.

The etching through the desorption of the reaction layer formed on the semiconductor wafer is accomplished using ion beams or plasma. The source of the ion beams or plasma is preferably an inert material.

### BRIEF DESCRIPTION OF THE DRAWINGS

The above objectives and advantages of the present invention will become more apparent by describing in detail preferred embodiments thereof with reference to the attached drawings in which:

FIG. 1 is a schematic view illustrating a semiconductor plasma etching apparatus according to an embodiment of the present invention;

FIG. 2 is a schematic view illustrating the beam source according to the embodiment;

FIG. 3 is a schematic diagram illustrating a mechanism of forming a reaction layer according to an embodiment of the present invention; and

FIG. 4 is a graph illustrating the etching characteristics of a SiO₂ layer and a Si₃N₄ layer when the SiO₂ layer is etched by the plasma etching apparatus according to an embodiment of the present invention.

### DETAILED DESCRIPTION OF A PREFERRED EMBODIMENT

Hereinafter, embodiments of the present invention will be described in detail with reference to the attached drawings. The present invention is not restricted to the following embodiments, and many variations are possible within the sprit and scope of the present invention. In the drawings, the same reference numerals denote the same members.

Referring to FIG. 1, a chamber 100 for accommodating a semiconductor wafer is provided. A radical source 102, a beam source 104, a wafer stage 106 and a neutralizer 108 are connected to the chamber 100. The radical source 102 supplies a radical into the chamber 100 by way of forming plasma and injecting the radical into the chamber. The plasma is preferably formed by an inductive coupled plasma method.

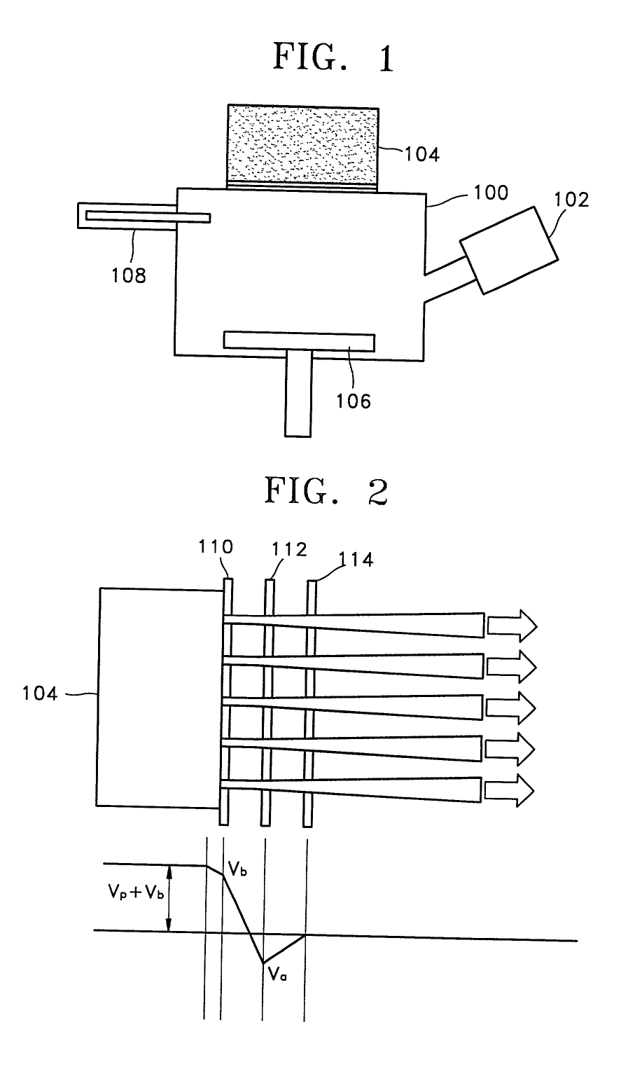

The beam source 104 supplies an ion beam or plasma into the chamber 100. The beam source 104 is an inductive coupled plasma apparatus, and is provided to adjust beam energy depending on the object being etched or etching conditions. Referring to FIG. 2 showing the ion beam or plasma acceleration principle in the beam source 104, the beam source 104 is preferably provided so that plasma or an ion beam can be accelerated using three grids such as a beam grid 110, an accelerating grid 112, and a ground grid 114. Alternatively, only two grids can be used. As shown in FIG. 2, when three grids are used, the voltage of the beam grid 110 is V_{b}, the voltage of the accelerating grid 112 is Vₐ, the ground grid 114 is grounded, and a plasma voltage within the beam source 104 is Vₚ. Here, the final beam energy of an ion beam or plasma accelerated and irradiated is Vₚ+V_{b}.

The chamber 100 is provided with the wafer stage 106 therein for supporting and holding an accommodated wafer. The wafer stage 106 has a cooling device for cooling the accommodated wafer. For example, a cooling device using deionized water may be provided for the wafer stage 106.

The neutralizer 108 is provided for neutralizing charge within the chamber 100 ionized by the ion beam, plasma or the radical described above. In other words, the neutralizer 108 supplies electrons into the chamber 100 cationized by the ion beam, plasma or the radical, thereby neutralizing the atmosphere of the chamber 100. The neutralizer 108 is preferably a hollow cathode emitter.

A method of etching semiconductor devices according to an embodiment of the present invention includes steps of forming a reaction layer on the surface of a semiconductor wafer through radical absorption and desorbing the reaction layer formed on the surface of the semiconductor wafer, thereby etching the surface of the wafer surface.

The semiconductor wafer surface may be composed of two different layers, an etching object layer and a layer other than the etching object layer. The reaction layer is formed on the etching object layer and the other layer. Preferably, the wafer surface is etched by desorbing the reaction layer formed on the semiconductor wafer surface such that an etching selectivity of the etching object layer to the other layer is high. The etching object layer on the wafer surface can be etched by repeatedly performing two or more times the step of forming the reaction layer through radical absorption and the etching step through radical desorption.

When etching the etching object layer on the surface of a wafer by repeatedly performing the reaction layer forming step through radical absorption and the etching step through radical desorption, it is preferable to increase an etching selectivity by adjusting the beam energy of an ion beam or plasma such that the layer other than the etching object layer is rarely etched. In other words, the beam energy of an ion beam or plasma is set such that the etching object layer is etched, but the material other than the etching object layer is rarely etched. Here, the etching object layer may be a SiO₂ layer, and the other layer may be a Si₃N₄ layer. The beam energy of an ion beam or plasma is preferably about 90-110 eV to increase the etching selectivity of the SiO₂ layer to the Si₃N₄ layer. As described later in a test example, when the beam energy of an ion beam or plasma is about 90-110 eV, a reaction layer on the surface of the SiO₂ layer is etched well, but a reaction layer on the surface of the Si₃N₄ layer is rarely etched. However, the beam energy may vary somewhat with the etching apparatus being used.

According to the embodiment of the present invention, a reaction layer is formed on the surface of a semiconductor wafer through radical absorption. The radical absorption is accomplished using the radical source 102 for supplying a radical into the chamber 100 accommodating a wafer. A preferred radical source gas is a mixed gas of a gas such as NH₃ or N₂ and H₂ containing H and N, and a gas such as NF₃, SF₆, CF₄, CHF₃, HF or XeF₂ containing F. Here, in the mixed gas of a gas containing H and N and gas containing F, the ratio of H to F is preferably 1.0 or over.

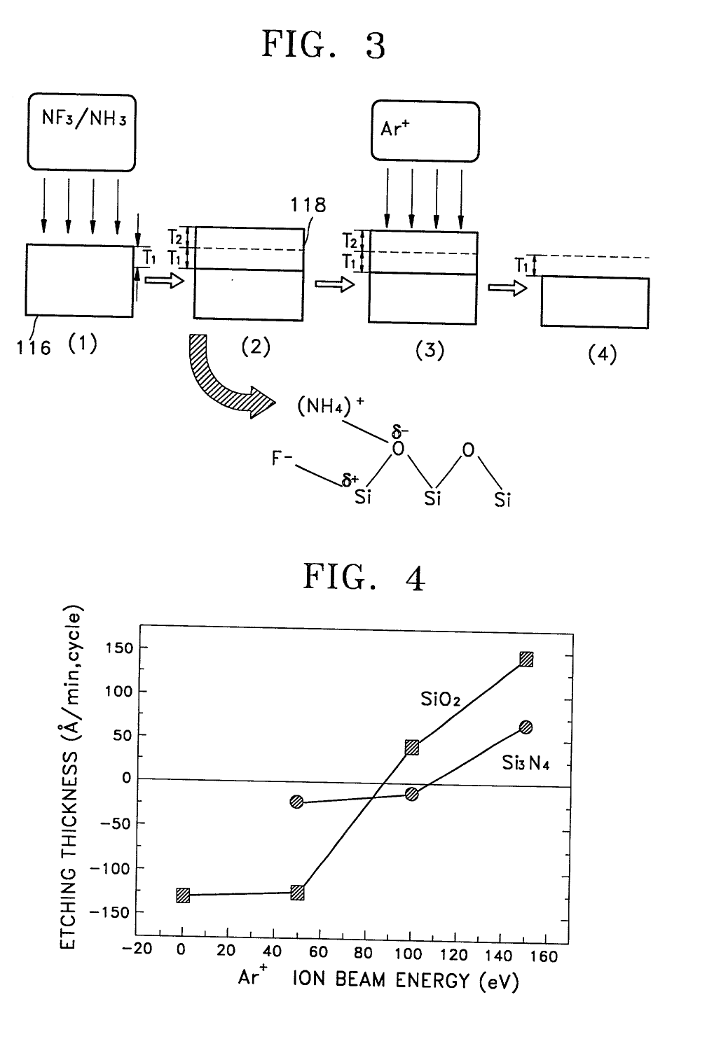

FIG. 3 is a schematic diagram illustrating a method of forming a reaction layer according to the embodiment of the present invention. The mechanism of forming a reaction layer on the surface of a semiconductor wafer which is an etching object layer, for example, the surface of a SiO₂ layer 116, will be described with reference to FIG. 3. First, a mixed gas of, for example, NH₃ and NF₃ is injected to the radical source 102 and transformed into a plasma (radical) state. The plasma (radical) is ejected from the radical source 102 into the chamber 100. The ejected radical is adsorbed to the surface of the SiO₂ layer 116 which is an etching object layer. A NH₄⁺ radical is absorbed to an oxygen radical carrying negative charge on its surface, and a F⁻ radical is absorbed to a silicon radical carrying positive charge on its surface. These absorbed radicals react with the SiO₂ layer 116, thereby forming a reaction layer 118. The reaction layer 118 is formed to have a predetermined depth T₁ beneath the surface of the SiO₂ layer 116 and have a predetermined thickness T₂ on the surface of the SiO₂ layer 116.

Thereafter, the surface of the semiconductor wafer is etched by desorbing the reaction layer 118 formed on the surface of the semiconductor wafer using ion beams or plasma. Preferably, the source of the ion beams or plasma is an inert material such as He, Ne, Ar, Kr or Xe. Referring to FIG. 3, the reaction layer 118 which is formed on the surface of the SiO₂ layer 116 through radical absorption is etched by ion beams or plasma emitted from the beam source 104, thereby etching the SiO₂ layer 116 to the predetermined thickness T₁.

To increase the etching selectivity of two different material layers according to the embodiment of the present invention, a reaction layer is thickly formed on an etching object layer, and a reaction layer is relatively thinly formed on the layer other than the etching object layer. In addition, beam energy is adjusted such that the etching object layer is etched well, and the other layer is rarely etched. When the etching object layer is a SiO₂ layer, and the other layer is a Si₃N₄ layer, the beam energy for obtaining the high etching selectivity of the SiO₂ layer to the Si₃N₄ layer is about 90-110 eV, whereby a reaction layer on the SiO₂ layer is well etched, but a reaction layer on the Si₃N₄ layer is rarely etched. Therefore, the etching selectivity of the SiO₂ layer to the Si₃N₄ layer can be increased by using the beam energy at which an etching object layer is well etched, and the layer other than the etching object layer is rarely etched. Moreover, an etching method according to the embodiment of the present invention is not subjected to an etch stop phenomenon, so that the etching method can be used for forming a narrow and long contact hole.

A process of performing etching under the state in which the etching selectivity of the SiO₂ layer to the Si₃N₄ layer is set to be high according to the embodiment of the present invention can be applied to a self-aligned contact (SAC) process. In other words, the SiO₂ layer/Si₃N₄ layer etching selectivity necessary for the SAC process can be greatly improved by repeatedly performing two or more times the steps of forming a reaction layer through radical absorption and desorbing the reaction layer according to the embodiment of the present invention. An etching method according to the embodiment of the present invention can also be used for an etching process for increasing the etching selectivity of a SiO₂ layer to a Si layer.

### TEST EXAMPLE

To form a radical, NH₃ was injected into the radical source 102 at 200 sccm, and NF₃ was injected into the radical source 102 at 100 sccm. Here, temperature and pressure was maintained at 20° C. and 760 mTorr. A radio frequency of 800 W was applied to the inductive coupled plasma coil of the radical source 102 for one minute to form a reaction layer on the surface of a wafer. Then, the thickness of the reaction layer was measured. Ar⁺ ion beams were formed by injecting Ar gas into the beam source 104 and irradiated on the wafer to remove the reaction layer. Here, a radio frequency of 200 W was applied to the inductive coupled plasma coil of the beam source 104 for one minute. The beam energy was 0-500 W.

FIG. 4 is a graph illustrating the etching characteristics of a SiO₂ layer and a Si₃N₄ layer when the SiO₂ layer is etched by the plasma etching apparatus according to an embodiment of the present invention. Referring to FIG. 4, the thickness of a reaction layer formed on the surface of the SiO₂ layer is about 125 Å. When the reaction layer is removed by irradiating Ar⁺ ion beams thereon for one minute while increasing the energy of the ion beams, the reaction layer is not removed at 50 eV. The reaction layer starts to be removed at ion beam energy of 80 eV, and the reaction layer is etched to about 150 Å at about 150 eV. Meanwhile, the thickness of a reaction layer formed on the surface of the Si₃N₄ layer is about 20 Å. It can be derived from this fact that formation of a reaction layer through radical absorption is subdued compared to the SiO₂ layer. The threshold ion beam energy at which the reaction layer formed on the Si₃N₄ layer is removed by the Ar⁺ ion beams is about 110 eV, which is higher compared to the SiO₂ layer. Even when ion beam energy of about 150 eV is applied, the reaction layer is etched to only about 60 Å, which is smaller than the SiO₂ layer.

According to the embodiment of the present invention, a reaction layer is selectively formed on the surface of a SiO₂ layer and the surface of a Si₃N₂ layer through radical absorption, and the reaction layer is etched under a state in which Ar⁺ ion beam energy is adjusted to 90-110 eV, thereby achieving a SiO₂ layer/Si₃N₂ layer etching property of a high selectivity in which the SiO₂ layer is etched, but the Si₃N₂ layer is not etched. Here, etched depth can be adjusted by repeatedly performing the step of forming a reaction layer through radical absorption and the etching step through radical desorption two or more times. It can be appreciated that the ion beam energy can be varied with a given plasma etching apparatus.

According to the present invention described above, a high etching selectivity can be achieved when an etching object layer is etched. In particular, the etching selectivity of a SiO₂ layer to a Si₃N₂ layer can be increased. In other words, a conventional SiO₂ layer/Si₃N₂ layer etching selectivity does not exceed 20:1, but a higher etching selectivity can be achieved according to an embodiment of the present invention.

In addition, an etch stop phenomenon caused by C—F polymer during conventional plasma etching can be prevented. Accordingly, a method of etching a semiconductor device according to the present invention can be used for forming a narrow and deep contact hole.

Although the invention has been described with reference to particular embodiments, the invention is not restricted thereto. It will be apparent to one of ordinary skill in the art that modifications of the described embodiment may be made without departing from the spirit and scope of the invention.

What is claimed is:

1. A semiconductor etching apparatus comprising:
a chamber for accommodating a wafer;
a radical source for supplying a radical into the chamber;
a beam source for supplying one of ion beams and plasma into the chamber;
a wafer stage for supporting and holding the wafer accommodated by the chamber; and
a neutralizer for neutralizing charge within the chamber ionized by the ion beams, plasma or the radical.

2. The semiconductor etching apparatus of claim 1, wherein the beam source is an inductive coupled plasma apparatus and wherein a beam energy of the beam source is adjustable.

3. The semiconductor etching apparatus of claim 1, wherein the beam source can accelerate the generated plasma or ion beams using three grids comprising a beam grid, an accelerating grid and a ground grid.

4. The semiconductor etching apparatus of claim 2, wherein the beam source can accelerate the generated plasma or ion beams using three grids comprising a beam grid, an accelerating grid and a ground grid.

5. The semiconductor etching apparatus of claim 1, wherein the radical source can form the plasma and eject the radical into the chamber.

6. The semiconductor etching apparatus of claim 5, wherein the plasma is formed by an inductive coupled plasma method.

7. The semiconductor etching apparatus of claim 1, wherein the neutralizer supplies electrons into the chamber cationized by the ion beams, plasma or the radical, thereby neutralizing the atmosphere of the chamber.

8. The semiconductor etching apparatus of claim 7, wherein the neutralizer is a hollow cathode emitter.

9. The semiconductor etching apparatus of claim 1, wherein the wafer stage comprises a cooling apparatus for cooling the accommodated wafer.

10. A method of etching semiconductor devices, comprising the steps of:
forming a reaction layer on the surface of a semiconductor wafer through radical absorption; and
etching the surface of the semiconductor wafer by desorbing the reaction layer formed on the surface of the semiconductor wafer.

11. The method of claim 10, wherein the surface of the semiconductor wafer is composed of two different layers, an etching object layer and an other layer, the reaction layer is formed on the etching object layer and the other layer, and the surface of the semiconductor wafer is etched by desorbing the reaction layer formed thereon such that the etching selectivity of the etching object layer to the other layer is high.

12. The method of claim 10, wherein the etching object layer on the surface of the semiconductor wafer is etched by repeatedly performing the step of forming the reaction layer through radical absorption and the etching step through radical desorption two or more times.

13. The method of claim I1, wherein the etching object layer on the surface of the semiconductor wafer is etched by repeatedly performing the step of forming the reaction layer through radical absorption and the etching step through radical desorption two or more times.

14. The method of claim 12, wherein the beam energy of ion beams or plasma is set such that the other layer except the etching object layer is rarely etched to thereby increase the etching selectivity when the etching object layer on the surface of the semiconductor wafer is etched, by repeatedly performing the reaction layer forming step through radical absorption and the etching step through radical desorption.

15. The method of claim 14, wherein the etching object layer is a SiO₂ layer, and the other layer is Si₃N₄ layer.

16. The method of claim 15, wherein the beam energy of the ion beams or plasma necessary for increasing the etching selectivity of the SiO₂ layer to the Si₃N₄ layer is 90-110 eV.

17. The method of claim 10, wherein the radical absorption is accomplished using a radical source for supplying a radical into a chamber accommodating a wafer.

18. The method of claim 17, wherein a mixed gas of a gas containing H and N and a gas containing F is used as the radical source gas.

19. The method of claim 18, wherein the mixed gas of a gas containing H and N and a gas containing F has a H/F ratio of 1.0 or higher.

20. The method of claim 10, wherein the etching through the desorption of the reaction layer formed on the semiconductor wafer is accomplished using ion beams or plasma, and wherein the source of the ion beams or plasma is an inert material.
